(19) United States
(12) Patent Application Publication
(10) Pub. No.: US 2003/0000645 A1
(43) Pub. Date: Jan. 2, 2003

(54) Apparatus and method for reducing leakage in a capacitor stack

(76) Inventor: Charles N. Dornfest, Fremont, CA (US)

Correspondence Address: APPLIED MATERIALS, INC., 2881 SCOTT BLVD. M/S 2061, SANTA CLARA, CA, 95050, US

(21) Appl. No.: 09/893,860

(22) Filed: Jun. 27, 2001

(51) Int. Cl. H01L 21/306; C23C 16/00

(52) U.S. Cl. 156/345.32; 118/719

(57) ABSTRACT

The present invention provides a unitary apparatus for manufacturing capacitor stacks to integrated circuits, the apparatus including a central wafer transfer chamber having a wafer transfer robot positioned therein and a wafer preparation chamber in communication with the central wafer processing chamber. The apparatus further includes a low thermal budget destabilizing chamber in communication with the central wafer transfer chamber and at least one wafer processing chamber in communication with a central wafer transfer chamber for depositing a dielectric layer on a wafer. The apparatus is configured so that the wafer preparation chamber and the low thermal budget destabilizing chamber cooperatively generate a first dielectric layer on a base electrode of a capacitor stack having minimal interface defects therebetween.

### BACKGROUND OF THE INVENTION

1. Field of the Invention

The present invention relates to reducing interface defects and leakage in integrated circuit capacitor stacks.

2. Background of the Related Art

A continuing trend in the semiconductor-based integrated circuit industry is to increase circuit density as much as possible while simultaneously minimizing the surface area required to support the increased circuit density. However, as current technology demands push integrated circuit densities into the 0.1 micron range, integrated circuit manufacturers are encountering substantial resistance to manufacturing efficient and reliable circuits, as these substantially smaller circuits are increasingly susceptible to failure resulting from surrounding and/or proximate electrical and environmental conditions. In particular, as integrated circuits begin to operate in the 0.1 micron range and smaller, the circuit components therein become increasingly sensitive to nearby electrical fields and conventional high temperature manufacturing conditions. As a result of this increased sensitivity, the operational characteristics of the components may become unpredictable, and therefore, undesirable for use.

Capacitive components, which generally form a substantial portion of integrated circuit components, are of particular concern in 0.1 micron and smaller devices, as capacitors of this size generally include very thin dielectric layers that are generally operating in a narrow range that borders upon dielectric breakdown. Dielectric breakdown, as is generally known in the art, refers to a condition where a dielectric material in a capacitor breaks down, generally as a result of an externally applied electric field, and no longer maintains it's desired dielectric properties. Therefore, as a result of the proximity of the capacitor operating range to dielectric breakdown in 0.1 micron integrated circuits, relatively small electric fields may push the operational range of the capacitor into a dielectric breakdown and/or leaking condition, which destroys the operational characteristics/performance of the capacitor and potentially the entire integrated circuit. Additionally, conventional manufacturing techniques for capacitors typically employ high temperature extended duration furnace-based nitridation methods. Although these methods have been successful in the past in the manufacture of larger integrated circuits, current 0.1 micron and smaller sized circuits suffer from transistor doping concentration degradation characteristics when manufactured in conventional high-temperature manufacturing environments.

In conventional multilayer film capacitor stacks, which are common in the semiconductor art, a dielectric breakdown condition generally begins when the dielectric properties, i.e., the dielectric strength of the dielectric material, of the capacitor stack begin to break down at a multilayer interface of the capacitor stack. Dielectric breakdown generally begins at a layer interface as a result of interface defects manufactured into the capacitor stack. In particular, capacitor stacks are commonly formed by depositing a thin nitride layer, i.e., silicon nitride, on a poly silicon lower electrode, and thereafter, depositing one or more dielectric layers on top of the nitride layer to form the capacitor stack. A top electrode may then be deposited on top of the dielectric layer(s) to compete the capacitor stack. However, conventional manufacturing techniques have inherently generated a large number of interface defects between the poly silicon lower electrode and the nitride layer, along with defects at the other interfaces in the capacitor stack. These interface defects, which often constitute weak chemical bonds at the interface resulting from not all of the bonds at the interface being properly linked, render 0.1 micron and smaller sized capacitor stacks susceptible to dielectric breakdown, as the weak bonds can be easily affected by a nominal electric field. In order to reduce these unlinked bonds/interface defects in conventional manufacturing techniques, the deposition process for the dielectric multilayers is often accomplished at high temperatures. High temperature deposition, such as that which is accomplished in batch furnace-type systems, generally operates to destabilize weak bonds at the interfaces through extended exposure to high temperatures in the furnace. Thereafter, the destabilized bonds and/or the atoms associated therewith may then be removed via low pressure, and as a result thereof, the interface defects may be reduced.

However, when dealing with 0.1 micron size devices, an increased thermal budget, such as the thermal budget associated with high temperature extended exposure batch furnace-type destabilization/deposition methods, often has a detrimental affect upon surrounding components. In particular, the high temperatures required to destabilize weak bonds at capacitor stack interfaces, which is generally 900° C. and higher for several hours in batch furnace-type systems, operates to degrade the doping concentrations of 0.1 micron size transistors to the point of rendering the transistors inoperable. Therefore, although conventional furnace-type manufacturing techniques attempt to address the capacitor interface defect situation, these techniques generally come at the price of degraded and/or inoperable transistor characteristics, as the high temperature duration employed in furnace-type systems degrades transistor doping characteristics.

Additionally, conventional apparatuses for manufacturing capacitor stacks for integrated circuits suffer from poor throughput rates. In particular, conventional methods often employ a stripping process to remove native oxides from the base electrode, which is often a wafer, and then a multiple wafer batch is run through a furnace to deposit a nitride layer, which often requires several hours to accomplish. After the nitride layer is deposited on each of the wafers in the furnace, generally the wafers are individually run through conventional film deposition apparatuses so that additional dielectric layer(s) may be formed thereon, the layers annealed, and the top electrode layer deposited thereon. Therefore, conventional methods generally employ at least two separate apparatuses, e.g., a furnace-type apparatus for depositing the nitride layer, and then a film deposition and annealing apparatus for depositing and annealing the dielectric and top electrode layers. The use of this combination of apparatuses generally requires several hours to complete formation of the various layers necessary to form the capacitor stack. As such, the throughput rate of conventional capacitor stack manufacturing devices is inherently much slower than the industry desires.

Therefore, in view of the continuing downsizing trend in the integrated circuit industry in conjunction with the deficiencies inherent in conventional integrated circuit manufacturing techniques, there exists a need for a manufacturing technique/apparatus capable of manufacturing a 0.1 micron and smaller integrated circuit capacitor stack capable of maintaining optimum operational characteristics in the presence of external electric fields. Additionally, there exists a need for an integrated circuit manufacturing apparatus/technique that employs a thermal budget capable of minimizing interface defects in a 0.1 micron and smaller capacitor stack without degrading the doping characteristics of proximate transistors to the point of rendering the transistors inoperable. Further still, there exists a need for a single apparatus and method for manufacturing a 0.1 micron and smaller capacitor stack, wherein the throughput rate of the apparatus and method is substantially faster than conventional apparatuses and methods.

### SUMMARY OF THE INVENTION

Embodiments of the invention generally provide a unitary apparatus for manufacturing capacitor stacks in integrated circuits, the apparatus including a central wafer transfer chamber having a wafer transfer robot positioned therein and a wafer preparation chamber in communication with the central wafer processing chamber. The apparatus further includes a low thermal budget destabilizing chamber in communication with the central wafer transfer chamber and at least one wafer processing chamber in communication with the central wafer transfer chamber for depositing a dielectric layer on a wafer. An annealing chamber is provided in communication with the central wafer transfer chamber. The apparatus is configured so that the wafer preparation chamber and the low thermal budget destabilizing chamber cooperatively generate a first dielectric layer on a base electrode of a capacitor stack having minimal interface defects therebetween.

Embodiments of the invention further provide a monolithic apparatus for manufacturing semiconductor capacitor stacks, wherein the apparatus includes a central wafer transfer chamber having at least one transfer robot positioned therein, and a wafer cleaning chamber in communication with the central wafer transfer chamber, the wafer cleaning chamber being configured to strip native oxides from a wafer surface and generate a hydrogen terminated barrier layer thereon. A bond destabilization chamber is provided in communication with the central wafer transfer chamber and is configured to break silicon-hydrogen bonds and deposit a first silicon nitride dielectric layer on the hydrogen terminated barrier layer. At least one dielectric deposition chamber configured to deposit dielectric layers upon a wafer is provided and is in communication with the central wafer transfer chamber. Further, an annealing chamber is provided in communication with the central wafer transfer chamber for annealing wafers.

Embodiments of the invention further provide a method for manufacturing a capacitor stack for an integrated circuit, wherein the method includes the steps of stripping native oxides from a surface of a wafer and depositing a nitride dielectric layer on the wafer surface. The method further includes the steps of depositing at least one additional dielectric layer on the wafer surface, annealing the wafer having the nitride layer and the at least one additional dielectric layer deposited thereon, and depositing an upper electrode layer on the previously deposited dielectric layer on the wafer.

### BRIEF DESCRIPTION OF THE DRAWINGS

So that the manner in which the above recited features, advantages and objects of the present invention may be understood in detail, a more particular description of the invention briefly summarized above may be had by reference to the embodiments thereof, which are illustrated in the appended drawings. It is to be noted, however, that the appended drawings illustrate only exemplary embodiments of the invention, and are therefore, not to be considered limiting of its scope, as the invention may admit to alternative equally effective embodiments not expressly illustrated by the drawings.

FIG. 1 illustrates an exemplary processing chamber configuration of the present invention.

FIG. 2 illustrates an exemplary remote plasma nitridation chamber of the present invention.

FIG. 3 illustrates an exemplary rapid thermal-processing chamber of the present invention.

FIG. 4 illustrates an exemplary capacitor stack.

### DETAILED DESCRIPTION OF THE PREFERRED EMBODIMENT

In order to manufacture reliable and efficient 0.1 micron and smaller integrated circuits having both transistors and capacitors formed thereon, the interface defects of the capacitor stacks should be minimized without damaging the physical characteristics of the surrounding transistors of the integrated circuit. Therefore, conventional furnace-type thermal-based methods for reducing the interface defects of a capacitor stack must be substantially improved in order to both effectively reduce the interface defects in capacitor stacks, as well as not damage the doping characteristics of transistors positioned proximate thereto. The present invention overcomes the deficiencies of conventional high temperature-based apparatuses and methods through application of a low thermal budget destabilizing process configured to minimize interface defects in integrated circuit capacitor stacks without disturbing the doping characteristics of transistors positioned proximate the capacitor stack. Additionally, the present invention accomplishes manufacture of an integrated circuit in a single apparatus, and therefore, generates substantially increased throughput rates over conventional apparatuses.

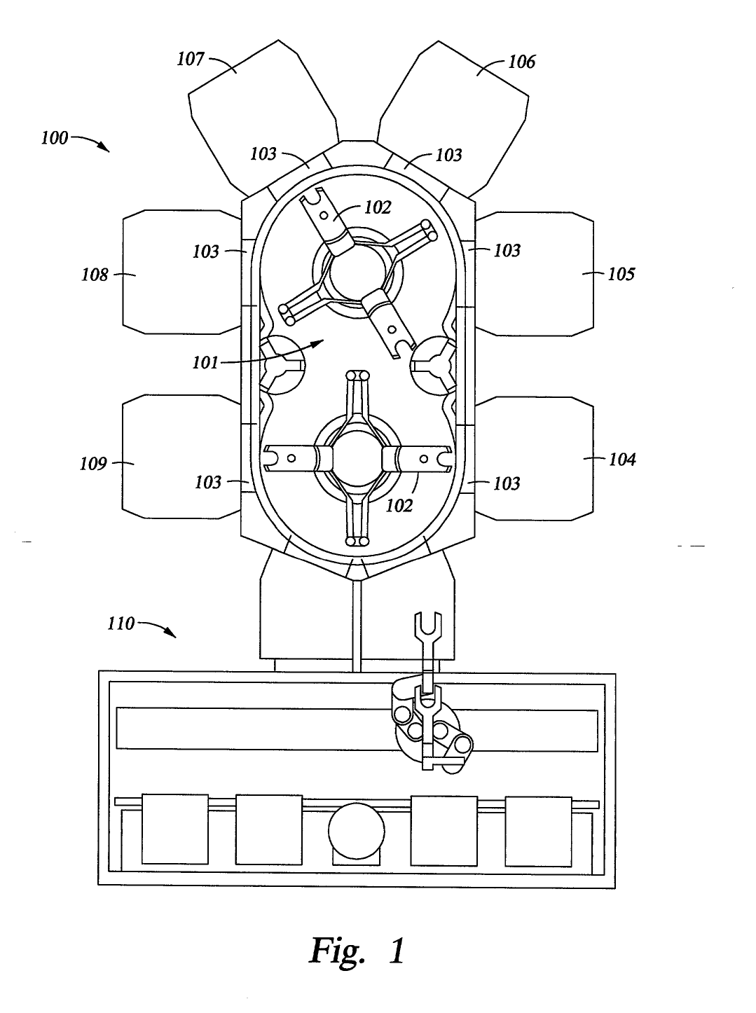

FIG. 1 illustrates a general configuration of a monolithic/unitary apparatus for manufacturing integrated circuits 100 having minimized interface defects in capacitor stacks. Apparatus 100 generally includes a central wafer transfer chamber 101 in communication with a plurality of surrounding wafer processing-type chambers 104-109. Wafer transfer chamber 101 generally includes a pumping system (not shown) configured to maintain a predetermined vacuum in transfer chamber 101. Additionally, a wafer loading/unloading module 110 which is generally known as a factory interface, may be included and configured to facilitate the placement and removal of wafers into and out of apparatus 100 without disturbing a vacuum created in transfer chamber 101. A gas supply system (not shown) may be configured to provide process and/or other gases to transfer chamber 101 and/or wafer processing chambers 104-109, as is known in the art.

Two wafer handling/transfer robots 102 are positioned in transfer chamber 101 and configured to transfer wafers between the various individual processing chambers 104-109 and wafer loading/unloading chamber 110. Individual processing chambers 104-109 may be selectively in communication with transfer chamber 101 via individual isolation valves 103 on each of processing chambers 104-109. Each of chambers 104-109 may be selectively isolated from transfer chamber 101 via isolation valve 103 during wafer processing, such that the pressure within transfer chamber 101 and the respective processing chambers 104-109 may be independently varied. Additionally, isolation valves 103 may be opened, thereby allowing robot 102 to extend into the respective processing chambers in order to manipulate and/or transfer wafers in and out of the respective chambers.

Additionally, although the present invention is described with respect to a configuration utilizing a central transfer chamber having a plurality of process chambers positioned about the central transfer chamber, the present invention is not limited to these cluster-type configurations. Alternatively, the present invention may be accomplished in varied processing configurations, including, but not limited to, linear processing apparatuses, batch process apparatuses, and/or other configurations suitable for the manufacture of capacitor stacks. In linear processing apparatuses, for example, wafers are inserted into the apparatus at a first end and are sequentially processed through the apparatus and are completed at a second end. In similar fashion to cluster configurations, linear systems may include several individual processing chambers and isolation chambers therein.

In one exemplary configuration of system 100 processing chamber 104 is configured to clean wafers prior to depositing one or more capacitive dielectric layers thereon. Therefore, for example, a poly silicon surface, or other surface that is to be used as a base electrode for a capacitor stack of an integrated circuit, may be cleaned prior to having any capacitive dielectric layers deposited thereon in clean/polish processing chamber 104. The cleaning process may be adapted to strip native oxides from the surface of the poly silicon surface, which is generally termed the base electrode, as well as to generate a hydrogen terminated barrier layer thereon. Both of these features facilitate minimization of defects at the interface between the poly silicon layer and the first dielectric layer subsequently deposited thereon, as native oxides promote weak bonds at the interface, and are therefore to be eliminated, while a hydrogen terminated surface promotes strong bonds at the interface, and is therefore desired. Exemplary surface cleaning methods may include acid vapor etching the layer, acid dipping the layer, and/or acid flushing the surface of the layer, as is known in the art. Further, remote plasma etching the layer, acid vapor etching the surface of the layer, exposing the surface to ultra violet light, or any combination thereof may also be utilized to clean the base electrode. Regardless of the particular cleaning method employed, the end result is to strip the surface of the poly silicon layer of native oxides, e.g., silicon oxides when a poly silicon wafer is used, which generally act to degrade dielectric properties of the layer interface between the base electrode and the first capacitor layer deposited thereon through generating weak bonds at the interface that may easily be influenced/altered by electric fields. This is critical to electrical components, as when bonds are influenced/altered by electric fields, the electrical properties of the components change as a result of the current generated by the bond being influenced/altered. Additionally, the above noted surface cleaning methods are calculated to create a hydrogen terminated surface on the layer, e.g., a barrier layer, which supports formation of strong bonds at the first capacitor layer interface, as well as inhibiting the formation of additional native oxides in the time period between cleaning and the deposition of the first dielectric layer.

Chamber 104, or another suitable chamber of chambers 105-09, may also be used to polish the hydrogen terminated surface of the base electrode layer after the cleaning process. In order to utilize chamber 104 for polishing, for example, a source of ultra violet light would have to be mounted above the wafer so that the ultra violet light emitted therefrom may be directed to contact the surface of the wafer. The polishing process may include low-pressure treatment of the wafer surface with ultra violet light. The pressure may be in the 1 millitorr range, while the temperature may be in the 600° to 700° C. range, or less. This type of polishing process for the poly silicon layer may further facilitate generation of a low silicon hydrogen bond surface on the base electrode. As such, the polishing process may be employed as an additional step to the cleaning processes, wherein the polishing process essentially operates to further facilitate the creation of the hydrogen terminated surface on the poly silicon layer.

Once the base electrode material, which is the poly silicon layer in the present exemplary embodiment, is cleaned by chamber 104, then the base electrode is generally ready to have the first capacitive layer deposited thereon. In this exemplary embodiment, the first dielectric layer may include a silicon nitride dielectric layer. Processing chambers 105 and/or 106 may be utilized to grow and/or deposit the first layer of silicon nitride on the base electrode.

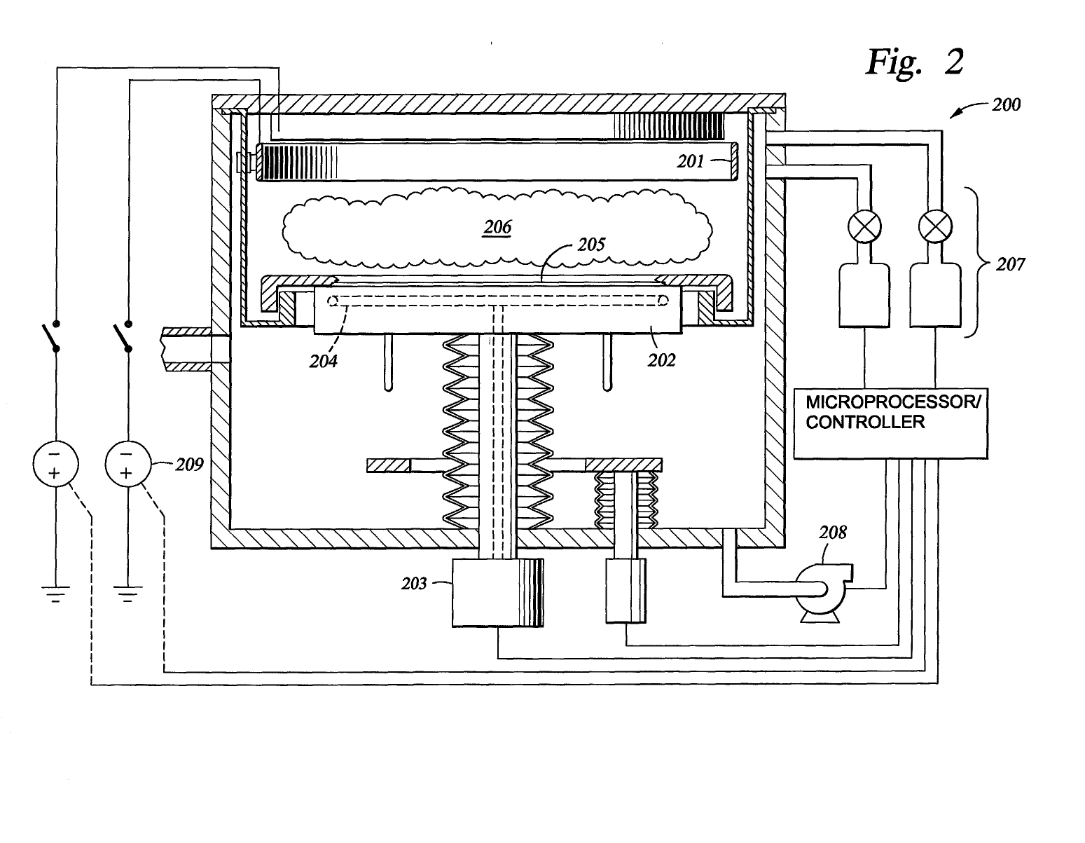

In this exemplary embodiment, processing chamber 105 may be configured to use plasma energy sufficient to break silicon-hydrogen bonds. Therefore, for example, chamber 105 may be configured as a decoupled plasma nitridation (DPN) chamber configured to generate an excited species using microwave energy. Alternatively, chamber 105 may be an active chemical-type species chamber configured to grow a first dielectric and/or nitride layer on the poly silicon base electrode while releasing any unlinked hydrogen bonds that may remain at the interface between the base electrode and the first dielectric/nitride layer via the heat generated in the process. An exemplary DPN processing chamber 200 is shown in FIG. 2. DPN chamber 200 generally includes a vacuum processing chamber having a coil 201 positioned above the position where a wafer 205 is to be located. Coil 201, which may be positioned inside or outside chamber 200, is generally in electrical communication with a power source 209, such as an RF energy power source, or other type of known power source. The wafer 205 is generally supported by a substantially planar wafer support member 202 that may be selectively movable, e.g., raised, lowered, and/or rotated, via a wafer support member actuation device 203. Additionally, wafer support member 202 may include embedded heating and/or cooling element 204 for selectively increasing and/or decreasing the temperature of the wafer support member 202 and the wafer 205 positioned thereon. A gas supply source 207 may be used to flow process gasses into DPN chamber 200, while a pumping device 208 may be used to maintain a predetermined vacuum in DPN chamber 200, as is generally known in the art.

In operation, a wafer may be placed on wafer support member 202 and DPN chamber 200 may be exhausted/pumped to a predetermined vacuum, in the millitorr range for example, via pumping device 208. A process gas, such as nitrogen, argon, helium, ammonium, or a combination thereof, may be introduced into DPN chamber 200 by gas supply source 207. Simultaneously, pumping device 208 may be pumping the interior volume of chamber 200 so that a constant vacuum pressure may be maintained within chamber 200. Power source 209 may then supply energy to coil 201, which may inductively excite the process gas within chamber 200 proximate the center of coil 201 into a plasma 206 above wafer 205, while an electrical bias is simultaneously applied to the wafer via a power source (not shown). Heating/cooling element 204 may be activated, which operates to rapidly increase the temperature of the wafer support member 202 and the wafer 205 positioned thereon. Alternatively, if the plasma 206 generates sufficient temperature, element 204 may be used to cool the substrate support member 202 and the wafer positioned thereon. The combination of the plasma, which emits ultra violet radiation that may be absorbed by the wafer, and the increased temperature provided by heating element 204, facilitates destabilization of the silicon hydrogen bonds on the surface of the wafer as well as growing a first dielectric/nitride layer on the base electrode as a result of the plasma deposition. Although the destabilization process in the DPN chamber is facilitated by the temperatures generated, generally in excess of 600° C., the energetic species from the plasma generally provides the primary energy for the destabilization process.

However, the DPN process may be carefully monitored, as the temperatures generated by plasma 206 may raise the temperature of wafer 205 well above 600° C. Although temperatures above 600° have been conventionally preferred to destabilize the silicon hydrogen bonds at the surface of wafer 205, extended exposure of wafer 205 to these temperatures may damage the physical characteristics of adjoining components on wafer 203. In particular, the doping characteristics of 0.1 micron and smaller transistors are known to be adversely affected by extended exposure to high temperatures, such as the extended high temperatures employed by conventional batch furnace-type devices. Therefore, the present invention may be configured to rapidly ramp up the temperature of wafer 205 in the DPN chamber 200 to a point sufficient to destabilize the silicon hydrogen bonds, and then cool wafer 205 prior to any damage being done to adjoining components, and in particular, adjoining transistors. This rapid heating and cooling process may operate to both destabilize the silicon hydrogen bonds without damaging transistors, and to deposit the first dielectric/nitride layer on the base electrode. Since the first layer grown in the DPN chamber is generally relatively thin, on the order of 10 to 15 angstroms, for example, the short time associated with the DPN temperature ramp is suitable. Additionally, although ammonium (NH₃) is disclosed as a potential process gas for DPN, ammonium is generally not the preferred gas, as conventional applications that utilize ammonium have been shown to suffer from increased silicon-hydrogen bonds, which is a disadvantage of conventional apparatuses that the present invention intends to address.

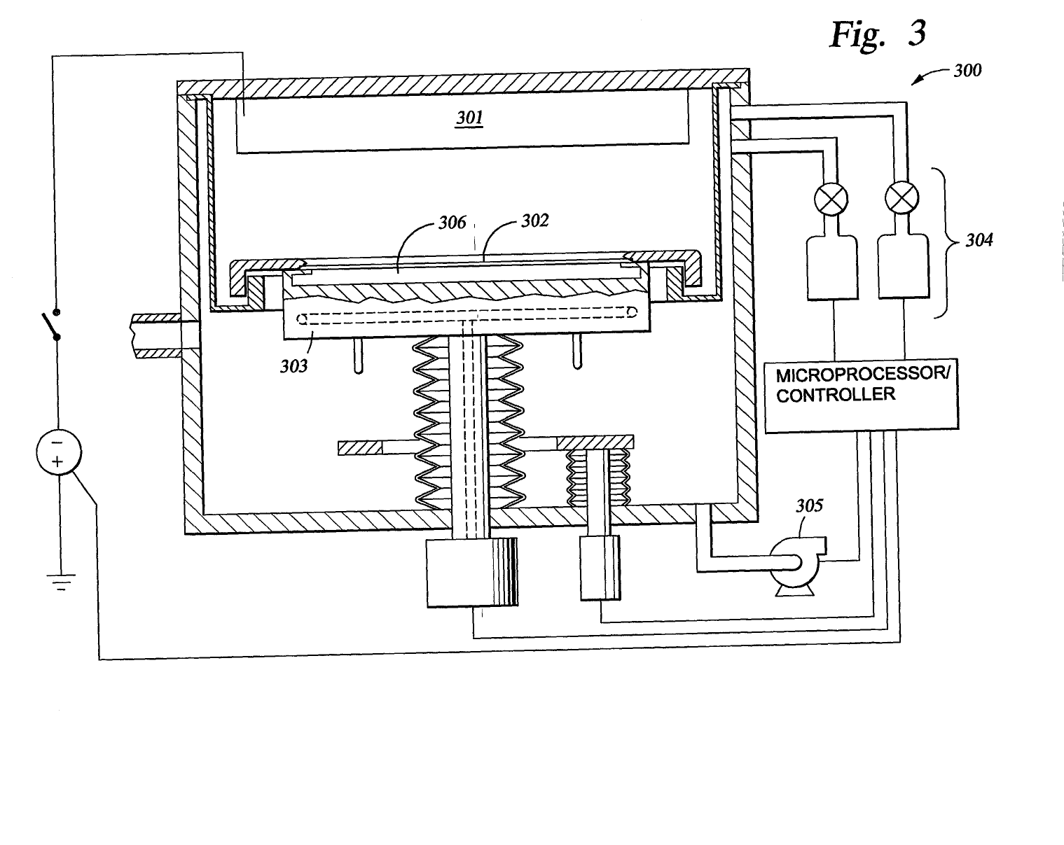

Alternatively, a rapid thermal nitriding (RTN) process may be used to grow the first dielectric/nitride layer on the base electrode. Therefore, a processing chamber, such as processing chamber 106, may be configured to support an RTN process through implementation of high ramp time heating devices, such as those used in a rapid thermal processing (RTP) chamber. Additionally, a cooled chamber and/or wafer support member may be employed to accelerate the temperature decrease after ramping to a temperature sufficient to destabilize the surface of a wafer. For example, a rapid thermal processing (RTP) chamber 300, such as the exemplary chamber shown in FIG. 3, may be used to conduct an RTN process on a wafer in order to grow the first dielectric/nitride layer of a capacitor stack on a base electrode wafer. RTP chamber 300 generally includes a gas supply source 304 and a vacuum source 305 both in communication with RTP chamber 300, which cooperatively operate to supply process gases and maintain a low pressure vacuum environment in the chamber 300. A heated and/or cooled wafer support member 303 may be used to support a wafer 302, wherein the wafer support member is generally positioned below a bank of high intensity lamps 301 mounted within chamber 300. Further, wafer support member 303 may be configured to support wafer 302 in a manner that allows a thermal void 306 to be formed behind wafer 302. This thermal void 306 may be used to assist in cooling wafer 302 after exposure to a rapid heating process. High intensity lamp bank 301 may be configured to rapidly supply heat to the chamber, and in particular, wafer 302, which operates to destabilize and eliminate any unlinked hydrogen atoms on the surface of the wafer. However, lamp bank 301 should be configured to ramp the temperature of wafer 302 from ambient/normal temperatures to the 700° C. to 800° C. range in only a few seconds. Therefore, lamp bank 301 is generally configured to provide a temperature ramp of 150° C. or more per second, which allows the temperature of wafer 302 to be ramped to 700° C. in just a few seconds. Chamber 300 may also be configured with cooling devices to rapidly cool chamber 300 down after the high temperature ramp process of RTP chamber 300. Additionally, substrate support 103 may be configured to support wafer 302 in a manner that allows air to circulate behind wafer 302 in the area designated by 306. This air circulation area may facilitate wafer 302 cooling after being exposed to a high ramp heating process.

Temperatures above 600° C., as discussed with regard to conventional devices, operate to destabilize silicon-hydrogen bonds at the surface of the wafer. Thereafter, the atoms destabilized from the high temperature, and in particular, the unbonded hydrogen atoms resident at the surface of the wafer, may be removed by the pumping device 305. However, in order to effectively grow the dielectric/nitride layer without damaging other components positioned proximate thereto, such as 0.1 micron and smaller transistors, the temperature and duration of an RTN and/or DPN process should be carefully controlled. In particular, although the temperature of the process may exceed 700° C., the duration of exposure of the wafer to temperatures above 700° C. may be minimized so that the destabilization process may occur without damaging doping concentrations of proximate transistors. Therefore, the present invention contemplates rapidly elevating the temperature of a wafer to a temperature sufficient to destabilize the surface of the wafer, maintaining the destabilizing temperature for a short period of time, and then cooling the wafer as quickly as possible. However, the destabilizing temperature is generally only maintained for a few seconds, or other time period calculated not to degrade doping characteristics of 0.1 micron transistors.

Although either DPN or RTP processes may be effective in destabilizing the silicon hydrogen bonds and depositing the first dielectric/nitride layer, the present invention is not limited to using one or the other of DPN or RTP processes.

As such, it is contemplated within the scope of the present invention that either RTP or DPN may be used, as well as a combination of DPN and RTP processes. The combination of RTP and DPN may be cooperatively used to further reduce the interface defects of the capacitor stack being formed, as each process contributes a reduction factor that when combined with the other process substantially reduces the probability of encountering an interface defect. For example, assuming that each method has a defect rate of one location per billion locations on the surface of the wafer, then if both methods are employed cooperatively, then the probability that a defect missed by one method will line up with a defect missed by the other method is approximately 1 over a billion squared. This extremely low probability results in an interface with very few defects and very low leakage characteristics, and therefore, a capacitor with strong dielectric properties may be formed, which is essential for 0.1 micron integrated circuit applications.

Once the first relatively thin dielectric/nitride layer has been formed on the lower electrode, which is generally 10-15 angstroms thick, then a second substantially thicker dielectric layer may be formed on top of the first layer. Therefore, using the exemplary configuration shown in FIG. 1, processing chamber 107 may be configured to deposit the second dielectric layer. Various techniques and apparatuses for depositing the second layer are contemplated within the scope of the present invention, including but not limited to physical vapor deposition, chemical vapor deposition, and/or methods known in the art. Therefore, processing chamber 107 may be configured with the devices necessary to implement the desired deposition method or technique. Further, the second dielectric layer, which as noted above is generally substantially thicker than the first dielectric/nitride layer, may be, for example, 60 to 80 angstroms thick. However, the present invention is not limited to capacitor stacks wherein the first dielectric/nitride layer is thinner than the second dielectric layer, as the first layer may be thicker than the second layer in certain embodiments of the present invention.

A third processing chamber 108 may be used to anneal the first and second dielectric layers deposited on the base electrode. Various known configurations and apparatus are available for annealing wafers, substrates, and other similar devices. The present invention contemplates using one or more of these known techniques for conducting a crystallization annealing process, as is known in the art, on the wafer having the first and second dielectric layers deposited thereon. For example, the crystalline annealing process may have a duration as small as 10 seconds or a large as 5 minutes or more, depending upon the material being annealed. Further the temperature of the anneal may range from 600° C. to 900° C. or more, depending upon the specific device geometry and composition. For example, smaller circuits, such as 0.1 micron-type circuits, will often be annealed near the 600° range, while larger circuits, such as, for example 0.35 micron-type circuits, may be annealed at substantially higher temperatures.

Another one of the processing chambers 109 may be used to deposit a third dielectric layer on top of the second dielectric layer, if necessary and/or desired by the particular application. In similar fashion to the second dielectric layer, the third dielectric layer may be deposited through a desired one of the known deposition and/or layer formation techniques. The third dielectric layer, which may also act as a portion of a top electrode for the capacitor stack, may be, for example, approximately 100 angstroms thick. If the third layer is not acting exclusively as the top electrode, then a layer of poly silicon may be placed on top of the third layer to cooperatively form the top electrode of the capacitor stack. However, in either situation, known deposition techniques may be used to form the respective layers of the capacitor stack.

Therefore, through the use of the exemplary embodiments illustrated in FIGS. 1 through 3, an apparatus for manufacturing capacitor stacks for 0.1 micron and smaller integrated circuits is provided. The capacitor base electrode layer may be stripped of native oxides and provided with a hydrogenated surface prior to using DPN and/or RTN techniques to deposit a nitride layer on the hydrogenated surface. Both the DPN and/or RTN techniques are calculated to rapidly increase the temperature of the base electrode to the point necessary to destabilize bonds at the surface of the base electrode, and then cool the base electrode so that doping characteristics of proximate transistors are not damaged. A dielectric layer may be deposited thereon, and the multilayer film subjected to a crystalline annealing process, as is known in the art. Thereafter, one or more additional layers may be deposited on the stack, including a top electrode layer. The complete stack may be annealed to generate a desired crystalline structure.

However, each step of the manufacturing process in the present invention may be conducted within a single manufacturing apparatus, such as the exemplary embodiment shown in FIG. 1. Therefore, the throughput time of the present exemplary embodiment is substantially shorter then conventional manufacturing apparatuses that utilize an extended duration batch-type furnace nitrating processes in conjunction with a separate chamber system. Furthermore, the present exemplary embodiment substantially reduces the possibility that additional native oxides will form on a cleaned base electrode, as the base electrode does not need to be transferred to a separate device through atmospheric conditions.

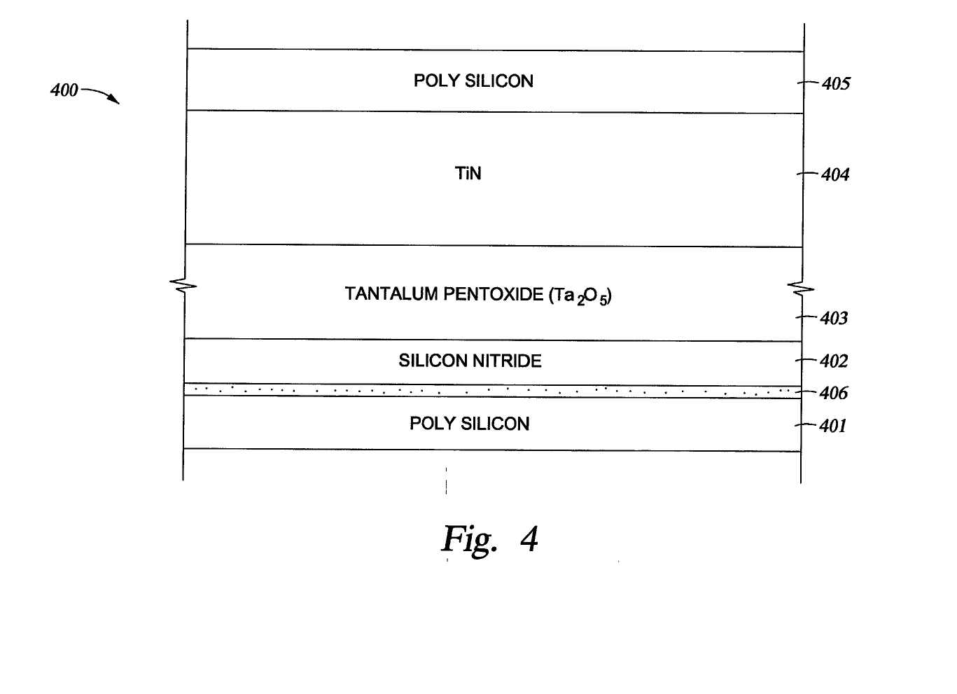

FIG. 4 illustrates an exemplary capacitor stack manufactured by the exemplary embodiment of the present invention shown in FIG. 1. The capacitor stack 400 illustrated in FIG. 4 includes a base electrode layer 401 of poly silicon. The upper working surface of base electrode layer 401 in its raw form may include various native oxides. Therefore, the working surface of base electrode 401 may be cleaned and/or polished prior to forming the remaining capacitor layers thereon, as the native oxides residing on the working surface of base electrode 401 are known to cause interface defects that substantially degrade the dielectric properties of the completed capacitor stack 400. As such, the working surface of the base electrode may be dipped or otherwise subjected to an acid solution, hydrofluoric or hydrocloric acid for example, in order to remove the native oxides therefrom. Aside from removing the native oxides, the acid exposure also operates to create a hydrogen terminated barrier-type working surface on base electrode 401. In addition to acid exposure, the working surface of base electrode 401 may be polished, via exposure to ultra-violet radiation, for example, in order to further prepare the working surface for receiving a capacitive layer thereon. Both the acid exposure surface cleanup process and the polishing process may be conducted in a single processing chamber, such as polishing/cleanup chamber 104 shown in the exemplary embodiment of FIG. 1.

Once the base electrode 401 working surface is prepared, base electrode 401 may be transferred to another processing chamber. In the exemplary embodiment shown in FIG. 1, for example, base electrode 401 may be transferred to DPN chamber 105 through the use of robot 102, which moves base electrode 401 from cleanup chamber 104 to DPN chamber 105 via transfer chamber 101. In this configuration, base electrode 401 is not exposed to the ambient atmosphere during the transfer from the cleanup chamber 104 to the DPN chamber 105, as transfer chamber 101 is also at a vacuum. Therefore, the probability of additional native oxides forming on the working surface is minimized. In addition to reducing the likelihood of native oxides and interface defects, the DPN process also substantially increases the throughput rates of the present invention over conventional methods and apparatuses. In particular, the present invention accomplishes cleaning/stripping, nitridation, annealing, and dielectric layer deposition in a single apparatus, while conventional methods generally employ a processing chamber and a separate furnace-type nitridation process.

Once base electrode 401 is placed within DPN chamber 105, then a 10 to 15 angstrom thick silicon nitride layer 402 may be formed on the working surface of the base electrode 401 through a remote plasma nitridation process. However, extended exposure of base electrode 401 to high temperatures that conventionally occur in DPN chambers is generally avoided. In particular, referring to the exemplary DPN chamber illustrated in FIG. 2, a process gas, such as a combination of argon and nitrogen may be introduced into the DPN chamber and a coil energized. The coil inductively generates a plasma that causes the silicon nitride layer 402 to be formed on the base electrode 401. Additionally, the DPN process operates to remove silicon hydrogen bonds, as the chamber temperature generally reaches at least 600° C., which is sufficient to destabilize the silicon hydrogen bonds. Achieving destabilization temperature may be aided by a heated support surface, which base electrode 401 may be position on for processing. Once destabilized, these bonds may be removed via the ambient vacuum pressure present in the DPN chamber. The temperature of the DPN chamber may be controlled through, for example, a microprocessor/computer control system interfacing with the coil power supply, the heater in the substrate support surface, and/or one or more chamber cooling devices.

Aside from the DPN process, a RTN process may be implemented, either alone or in combination with the DPN process, in order to remove the unwanted silicon hydrogen bonds on the working surface of base electrode 401. The exemplary RTP chamber shown in FIG. 3 may be used, for example, for rapidly heating base electrode 401 to a temperature sufficient to destabilize the silicon hydrogen bonds on the working surface of base electrode 401. The present invention contemplates that the exemplary RTP chamber may heat the base electrode to over 700° C. in just a few seconds through a high intensity lamp bank positioned within the RTP chamber. Once base electrode 401 is heated to a temperature sufficient to destabilize the bonds on the working surface, then base electrode may be cooled to avoid prolonged exposure to high temperatures, which may damage other components proximate thereto. In similar fashion to the DPN chamber, the exemplary RTP chamber may also be computer controlled in order to precisely control process temperatures and/or other parameters.

The process of using DPN or RTP substantially improves the electrical properties of the interface 406 between the base electrode poly silicon layer 401 and the silicon nitride layer 402 by removing weak or unlinked bonds therefrom, and in particular, silicon-hydrogen bonds. Through the use of the RTP or DPN chambers discussed above, interface defects within interface 406, which result from weak or unlinked bonds, are minimized and potentially removed. Therefore, the leakage characteristics of the capacitor stack are substantially improved, as the unlinked bonds removed by the DPN and/or RTP processes are generally a primary cause of capacitor leakage.

Once the relatively thin silicon nitride layer 402 is grown on base electrode 401, then the first dielectric layer 403 may be deposited thereon. First dielectric layer 403, in the present exemplary embodiment, may be a tantalum pentoxide layer having a thickness of approximately 60 to 80 angstroms. This layer may be deposited on top of the nitride layer 402 by transporting the base electrode 401 having the nitride layer 402 thereon to a processing chamber, such as processing chamber 107 in FIG. 1, for example, that may be configured to deposit tantalum oxide. The tantalum oxide layer 403 may be deposited on top of the nitride layer 402 through known deposition techniques.

After the tantalum oxide layer 403 is deposited, the multilayer capacitor stack may be annealed to obtain the desired crystalline structure and/or to prevent oxidation of the top portion of the capacitor stack. Therefore, the capacitor stack 400 may be transported from the processing chamber for depositing the tantalum oxide to an annealing chamber, such as chamber 108 shown in FIG. 1. The annealing process, which may take place in a dedicated annealing chamber, such as processing chamber 108 in FIG. 1, generally includes annealing the capacitor stack 400 at temperatures below 700° C. The duration and pressure of the anneal may be calculated to optimize the crystalline structure, as is known in the art. Furthermore, the anneal may also be configured to repair oxygen deficiency defects, i.e., the temperature may be chosen to eliminate additional oxygen defects from the stack, as is known in the art. Although the present embodiment of the invention illustrates that two annealing chambers may be used, the present invention contemplates that a single annealing chamber may be configured and used to conduct both annealing processes of the invention, assuming that the use of a single annealing chamber does not substantially affect throughput.

After the capacitor stack 400 is annealed, a top electrode layer 404 may be deposited on the capacitor stack. The top electrode layer 404 in the present exemplary capacitor stack is a titanium nitrogen compound having a thickness of approximately 100 angstroms or more. The top electrode layer 404 may be deposited by a processing chamber, such as, for example, processing chamber 109 in FIG. 1. Therefore, assuming that the configuration of FIG. 1 is used, robot 102 would transport the capacitor stack 400 from the annealing chamber 108 to the processing chamber 109 configured to deposit the titanium nitrogen compound top electrode layer 404. Additionally, another top electrode layer 405 may be deposited and/or placed on electrode layer 404, if desired.

While foregoing description is directed to the exemplary embodiments of the present invention, other additional embodiments of the present invention may be devised without departing from the true scope thereof, wherein the true scope of the present invention may be determined by reference to the metes and bounds of the following claims.

What is claimed is:

1. A unitary apparatus for manufacturing capacitor stacks in integrated circuits, comprising:
a central wafer transfer chamber having at least one wafer transfer robot positioned therein;
a wafer preparation chamber in communication with the central wafer processing chamber;
a low thermal budget destabilizing chamber in communication with the central wafer transfer chamber; and
at least one wafer processing chamber in communication with a central wafer transfer chamber for depositing a dielectric layer on a wafer,
wherein the wafer preparation chamber and the low thermal budget destabilizing chamber are configured to cooperatively generate a first dielectric layer on a base electrode of a capacitor stack having minimal interface defects therebetween.

2. The apparatus of claim 1, wherein the wafer preparation chamber further comprises at least one of an acid dip chamber, an acid vapor etch chamber, an acid flush chamber, a remote plasma etching chamber, and a high intensity ultra violet light chamber.

3. The apparatus of claim 1, wherein the wafer preparation chamber is configured to strip native oxides from a base electrode layer of a capacitor stack.

4. The apparatus of claim 1, wherein the wafer preparation chamber is configured to generate a hydrogen terminated barrier surface on the base electrode.

5. The apparatus of claim 1, wherein the low thermal budget destabilizing chamber further comprises a chamber configured to generate an excited species using microwave energy.

6. The apparatus of claim 1, wherein the low thermal budget destabilizing chamber further comprises a decoupled plasma nitridation chamber.

7. The apparatus of claim 1, wherein the low thermal budget destabilizing chamber further comprises a rapid thermal processing chamber.

8. The apparatus of claim 1, wherein the at least one wafer processing chamber further comprises at least one of a physical vapor deposition chamber and a chemical vapor deposition chamber.

9. The apparatus of claim 1, further comprising an annealing chamber in communication with the central wafer transfer chamber, the annealing chamber being configured to conduct a crystalline annealing process at a temperature of at least 600° C.

10. A monolithic apparatus for manufacturing semiconductor capacitor stacks, the apparatus comprising:
a reduced pressure central wafer transfer chamber having at least one transfer robot positioned therein;
a wafer cleaning chamber in communication with the central wafer transfer chamber, the wafer cleaning chamber being configured to strip native oxides from a wafer surface and generate a hydrogen terminated barrier layer thereon;
a bond destabilization chamber in communication with the central wafer transfer chamber, the bond destabilization chamber being configured to break silicon-hydrogen bonds and deposit a first silicon nitride dielectric layer on the hydrogen terminated barrier layer; and
at least one dielectric layer deposition chamber in communication with the central wafer transfer chamber and being configured to deposit a second dielectric layer.

11. The apparatus of claim 10, wherein the bond destabilization chamber further comprises a decoupled plasma nitridation chamber.

12. The apparatus of claim 10, wherein the bond destabilization chamber further comprises a rapid thermal processing chamber configured to rapidly increase the temperature of the wafer surface in order destabilize the silicon-hydrogen bonds thereon.

13. The apparatus of claim 10, wherein the wafer cleaning chamber further comprises at least one of an acid dip chamber, an acid flush chamber, an acid based vapor etch chamber, a remote plasma etching chamber, and a high intensity ultra violet light chamber.

14. The apparatus of claim 10, further comprising a polishing chamber for polishing the wafer surface subsequent to the native oxides being stripped therefrom.

15. The apparatus of claim 10, wherein the polishing chamber includes an ultraviolet light emission source configured to expose the wafer surface to ultraviolet light.

16. The apparatus of claim 10, wherein the bond destabilization chamber further comprises a chamber configured to generate an excited species using microwave energy.

17. The apparatus of claim 10, wherein the at least one dielectric layer deposition chamber further comprises at least one of a physical vapor deposition chamber and a chemical vapor deposition chamber.

18. The apparatus of claim 10, further comprising an annealing chamber configured to conduct a crystalline annealing process at a temperature of at least 600° C.

19. A method for manufacturing a capacitor stack for an integrated circuit, the method comprising the steps of:
stripping native oxides from a wafer surface of a wafer;
depositing a nitride dielectric layer on the wafer surface;
depositing at least one additional dielectric layer on the wafer surface;
annealing the wafer having the nitride layer and the at least one additional dielectric layer deposited thereon; and
depositing an upper electrode layer.

20. The method of claim 19, wherein stripping native oxides further comprises generating a hydrogen terminated wafer surface.

21. The method of claim 19, wherein stripping the native oxides further comprises polishing the hydrogen terminated wafer surface.

22. The method of claim 19, wherein stripping native oxides further comprises at least one of acid dipping the wafer surface, acid flushing the wafer surface, acid vapor etching the wafer surface, remote plasma etching the wafer surface, and exposing the wafer surface to ultra violet light.

23. The method of claim 19, wherein depositing a nitride dielectric layer on the wafer surface further comprises placing the wafer in a decoupled plasma nitridation chamber.

24. The method of claim 19, wherein depositing a nitride dielectric layer on the wafer surface further comprises placing the wafer in a rapid thermal process chamber.

25. The method of claim 19, wherein depositing a nitride dielectric layer on the wafer surface further comprises:
rapidly increasing a temperature of the wafer surface to a temperature calculated to destabilize unwanted bonds on the wafer surface; and
cooling the temperature of the wafer surface before doping characteristics of adjacent transistors are damaged.

26. The method of claim 19, wherein depositing at least one additional dielectric layer on the wafer surface further comprises using at least one of a physical vapor deposition chamber and a chemical vapor deposition chamber.

27. The method of claim 19, wherein annealing the wafer further comprises heating the capacitor stack to a temperature calculated to generate a desired crystalline structure.
